(19) United States
(12) Patent Application Publication
(10) Pub. No.: US 2023/0371350 A1
(43) Pub. Date: Nov. 16, 2023

(54) DISPLAY DEVICE

(71) Applicant: Japan Display Inc., Tokyo (JP)

(72) Inventor: Tomohiko NAGANUMA, Tokyo (JP)

(73) Assignee: Japan Display Inc., Tokyo (JP)

(21) Appl. No.: 18/305,391

(22) Filed: Apr. 24, 2023

(30) Foreign Application Priority Data
May 16, 2022 (JP) 2022-080067

(51) Int. Cl. H10K 59/80; H10K 59/122; H10K 59/13

(52) U.S. Cl. CPC H10K 59/8792; H10K 59/122; H10K 59/13

(57) ABSTRACT

Disclosed is a display device including a plurality of pixels, a first inorganic film, a light-shielding film, a resin film, and a second inorganic film. The plurality of pixels each has a light-emitting element including a pixel electrode, an electroluminescence layer over the pixel electrode, and a counter electrode over the electroluminescence layer. The first inorganic film is located over the counter electrode. The light-shielding film is located over the first inorganic film and has a plurality of openings overlapping the pixel electrodes of the plurality of pixels. The resin film is located over the light-shielding film and the first inorganic film and is in contact with the first inorganic film. The second inorganic film is located over the resin film.

### CROSS REFERENCE TO RELATED APPLICATIONS

This application claims the benefit of priority to Japanese Patent Application No. 2022-080067, filed on May 16, 2022, the entire contents of which are incorporated herein by reference.

### FIELD

An embodiment of the present invention relates to a display device having a light-emitting element. Alternatively, an embodiment of the present invention relates to a photosensor device having a sensor element.

### BACKGROUND

As photoelectric conversion elements mounted on display devices and photosensor devices, elements containing organic compounds in an active layer have been known. For example, organic EL (Electroluminescent) display devices in which elements (organic electroluminescence elements) using the electroluminescence of organic compounds are mounted in each pixel have recently launched on the market. In Japanese Patent Application Publication No. 2017-98255, it is disclosed that the display quality of an organic EL display device can be improved by providing a light-shielding film on a counter substrate sealing the organic electroluminescence elements fabricated on a substrate.

### SUMMARY

An embodiment of the present invention is a display device. The display device includes a plurality of pixels, a first inorganic film, a light-shielding film, a resin film, and a second inorganic film. The plurality of pixels each has a light-emitting element including a pixel electrode, an electroluminescence layer over the pixel electrode, and a counter electrode over the electroluminescence layer. The first inorganic film is located over the counter electrode. The light-shielding film is located over the first inorganic film and has a plurality of openings overlapping the pixel electrodes of the plurality of pixels. The resin film is located over the light-shielding film and the first inorganic film and is in contact with the first inorganic film. The second inorganic film is located over the resin film.

An embodiment of the present invention is a display device. The display device includes a plurality of pixels, a light-shielding film, a first inorganic film, a resin film, and a second inorganic film. The plurality of pixels each has a light-emitting element including a pixel electrode, an electroluminescence layer over the pixel electrode, and a counter electrode over the electroluminescence layer. The light-shielding film is located over the counter electrode and has a plurality of openings overlapping the pixel electrodes of the plurality of pixels. The first inorganic film is located over the light-shielding film and the counter electrode. The resin film is located over and in contact with the first inorganic film. The second inorganic film is located over and in contact with the resin film.

An embodiment of the present invention is a display device. The display device includes a plurality of pixels, a light-shielding film, a first inorganic film, a resin film, and a second inorganic film. The plurality of pixels each has a light-emitting element including a pixel electrode, an electroluminescence layer over the pixel electrode, and a counter electrode over the electroluminescence layer. The light-shielding film is located between the electroluminescence layer and the counter electrode and has a plurality of openings overlapping the pixel electrodes of the plurality of pixels. The first inorganic film is located over the light-shielding film and the counter electrode. The resin film is located over and in contact with the first inorganic film. The second inorganic film is located over the resin film.

An embodiment of the present invention is a photosensor device. The photosensor device includes a plurality of sensor elements, a first inorganic film, a light-shielding film, a resin film, and a second inorganic film. The plurality of sensor elements each includes a first electrode, a photoelectric conversion layer over the first electrode, and a second electrode over the photoelectric conversion layer. The first inorganic film is located over the second electrode. The light-shielding film is located over the first inorganic film and has a plurality of openings overlapping the first electrodes of the plurality of sensor elements. The resin film is located over the light-shielding film and the first inorganic film and in contact with the first inorganic film. The second inorganic film is located over the resin film.

An embodiment of the present invention is a photosensor device. The photosensor device includes a plurality of sensor elements, a light-shielding film, a first inorganic film, a resin film, and a second inorganic film. The plurality of sensor elements each includes a first electrode, a photoelectric conversion layer over the first electrode, and a second electrode over the photoelectric conversion layer. The light-shielding film is located over the second electrode and has a plurality of openings overlapping the first electrodes of the plurality of sensor elements. The first inorganic film is located over the light-shielding film and the second electrode. The resin film is located over and in contact with the first inorganic film. The second inorganic film is located over and in contact with the resin film.

An embodiment of the present invention is a photosensor device. The photosensor device includes a plurality of sensor elements, a light-shielding film, a first inorganic film, a resin film, and a second inorganic film. The plurality of sensor elements each includes a first electrode, a photoelectric conversion layer over the first electrode, and a second electrode over the photoelectric conversion layer. The light-shielding film is located between the photoelectric conversion layer and the second electrode and has a plurality of openings overlapping the first electrodes of the plurality of sensor elements. The first inorganic film is located over the light-shielding film and the second electrode. The resin film is located over and in contact with the first inorganic film. The second inorganic film is located over the resin film.

### BRIEF DESCRIPTION OF DRAWINGS

FIG. 1 is a schematic top view of a display device according to an embodiment of the present invention.

FIG. 2 is a schematic cross-sectional view of a part of the display device according to an embodiment of the present invention.

FIG. 3A is a schematic cross-sectional view of a light-emitting element included in a display device according to an embodiment of the present invention.

FIG. 3B is a schematic cross-sectional view of a light-emitting element included in a display device according to an embodiment of the present invention.

FIG. 3C is a schematic cross-sectional view of a light-emitting element included in a display device according to an embodiment of the present invention.

FIG. 4A is a schematic cross-sectional view of a part of a display device according to an embodiment of the present invention.

FIG. 4B is a schematic cross-sectional view of a part of a display device according to an embodiment of the present invention.

FIG. 5A is a schematic cross-sectional view of a part of a display device according to an embodiment of the present invention.

FIG. 5B is a schematic cross-sectional view of a part of a display device according to an embodiment of the present invention.

FIG. 5C is a schematic cross-sectional view for explaining an effect of a light-shielding film included in a display device according to an embodiment of the present invention.

FIG. 6A is a schematic cross-sectional view of a part of a display device according to an embodiment of the present invention.

FIG. 6B is a schematic cross-sectional view of a part of a display device according to an embodiment of the present invention.

FIG. 6C is a schematic cross-sectional view of a part of a display device according to an embodiment of the present invention.

FIG. 7A is a schematic cross-sectional view of a part of a display device according to an embodiment of the present invention.

FIG. 7B is a schematic cross-sectional view of a part of a display device according to an embodiment of the present invention.

FIG. 7C is a schematic cross-sectional view of a part of a display device according to an embodiment of the present invention.

FIG. 8 is a schematic cross-sectional view of a part of a display device according to an embodiment of the present invention.

FIG. 9 is a schematic top view of a photosensor device according to an embodiment of the present invention.

FIG. 10 is a schematic cross-sectional view of a part of a photosensor device according to an embodiment of the present invention.

FIG. 11A is a schematic cross-sectional view of a part of a photosensor device according to an embodiment of the present invention.

FIG. 11B is a schematic cross-sectional view for explaining an effect of a light-shielding film included in a photosensor device according to an embodiment of the present invention.

FIG. 12A is a schematic cross-sectional view of a part of a photosensor device according to an embodiment of the present invention.

FIG. 12B is a schematic cross-sectional view of a part of a photosensor device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure.

The same reference number is used when plural structures which are the same as or similar to each other are collectively represented, while a hyphen and a natural number are further used when these structures are independently represented.

### FIRST EMBODIMENT

In this embodiment, a display device 100 according to an embodiment of the present invention is explained.

### 1. Overall Structure

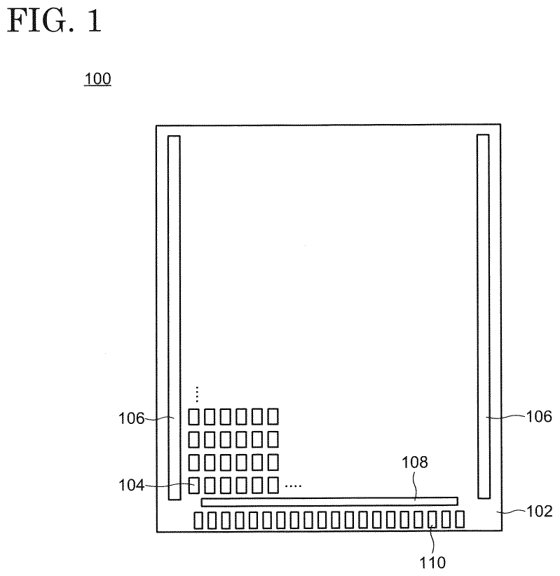

A schematic top view of the display device 100 is shown in FIG. 1. The display device 100 has a substrate 102, on which a variety of patterned insulating films, semiconductor films, and conductive films are stacked. These insulating films, semiconductor films, and conductive films form a plurality of pixels 104, driver circuits for driving the plurality of pixels 104 (scanning line driver circuits 106, signal line driver circuit 108), and a variety of wirings (not illustrated). The single smallest region surrounding all of the plurality of pixels 104 is a display region, and the region surrounding the display region is called a peripheral region or a frame region. As described below, a light-emitting element is disposed in each pixel 104.

The wirings, which are not illustrated, extend from the pixels 104, the scanning line driver circuits 106, and the signal line driver circuits 108, and are exposed at a vicinity of an edge of the substrate 102 to form terminals 110. An external circuit (not illustrated) is connected to the terminals 110 via a connector such as a flexible printed circuit board (FPC). The scanning line driver circuits 106 and the signal line driver circuit 108 generate various signals on the basis of a variety of signals and power supplied from the external circuit, and the pixels 104 are controlled on the basis of these signals to display images in the display region.

### 2. Structure of Pixel

### 2-1. Pixel Circuit

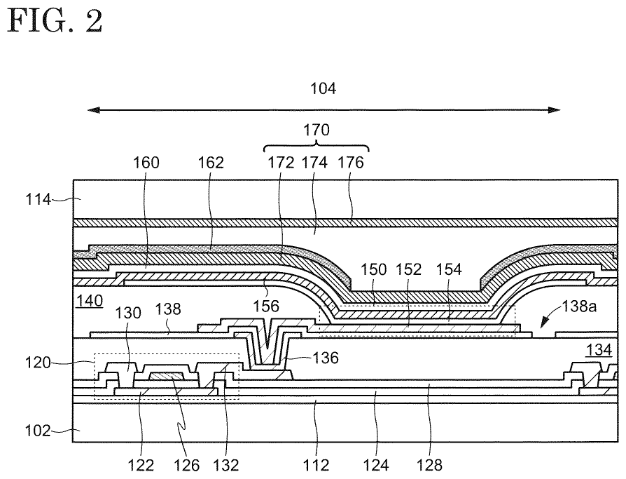

FIG. 2 shows a schematic cross-sectional view of the pixel 104 including the light-emitting element 150. In each pixel 104, a pixel circuit for controlling the light-emitting element 150 is provided together with the light-emitting element 150. Although FIG. 2 shows a single transistor 120 connected to the light-emitting element 150 as one of the components of the pixel circuit, the structure of the pixel circuit may be arbitrarily selected, and the pixel circuit may be appropriately configured with one or more transistors and capacitor elements.

As shown in FIG. 2, the pixel circuit including the transistor 120 and the like is provided over the substrate 102 directly or through an undercoat 112 which is an optional component. The substrate 102 is a base material supporting the pixel circuits and the light emitting elements 150 and may include an inorganic material such as glass, quartz, silicon, and sapphire or a polymer such as a polyimide, a polyester, and a polycarbonate. The substrate 102 may have flexibility so that it can be elastically deformed. The undercoat 112 is provided to prevent impurities contained in the substrate 102 from diffusing into the pixel circuit and may be composed of one or more films containing a silicon-containing inorganic compound such as silicon nitride, silicon oxide, silicon nitride oxide, and silicon oxynitride.

The transistor 120 illustrated in FIG. 2 is structured with a semiconductor film 122, a gate insulating film 124 over the semiconductor film 122, a gate electrode 126 over the gate insulating film 124, a first interlayer film 128 over the gate electrode 126 as well as a source electrode 130 and a drain electrode 132 electrically connected to the semiconductor film 122 through openings formed in the gate insulating film 124 and the first interlayer film 128. The structure of the transistor 120 demonstrated here is an example, and transistors having a variety of structures can be arranged in each pixel circuit. For example, not only the top-gate type transistor shown in FIG. 2, but also a bottom-gate type transistor or a transistor in which the gate electrodes are arranged over and below the semiconductor film may be employed. In addition, the semiconductor contained in the semiconductor film 122 is not limited to Group 14 elements such as silicon and germanium, but may be an oxide semiconductor including oxides of Group 13 elements such as indium oxide and gallium oxide. The gate insulating film 124 and the first interlayer film 128 may also be formed with a silicon-containing inorganic compound. The gate insulating film 124 may include an insulator having a high relative permittivity such as hafnium silicate, zirconium silicate, hafnium oxide, or zirconia. The gate electrode 126, the source electrode 130, and the drain electrode 132 may include a metal such as molybdenum, tungsten, tantalum, titanium, copper, and aluminum, and may be formed by applying a sputtering method, a chemical vapor deposition (CVD) method, or the like.

### 2-2. Light-Emitting Element

A planarization film 134 containing a polymer such as a polyimide, a silicon resin, a polyester, an acrylic resin, or the like is provided over the transistor 120, by which unevenness caused by the transistor 120 and the transistors and capacitor elements which are not shown is absorbed to provide a flat surface. The light-emitting element 150 is disposed over the planarization film 134. The light-emitting element 150 has a pixel electrode 152, an electroluminescence layer 154 over the pixel electrode 152, and a counter electrode 156 over the electroluminescence layer 154 as its fundamental components. The pixel electrode 152 is electrically connected to the drain electrode 132 exposed in an opening in the planarization film 134, either directly or through an optional configuration of a connecting electrode 136. A second interlayer film 138 including a silicon-containing inorganic compound may be formed between the planarization film 134 and the pixel electrode 152. Although not illustrated, when the second interlayer film 138 is provided, it is also possible to form a capacitor element using it as a dielectric film. Note that, impurities such as water and oxygen contained in the planarization film 134 can be removed by providing an opening 138a exposing a portion of the planarization film 134 in the second interlayer film 138.

A bank (also called a partition wall) 140 is provided over the pixel electrode 152 to cover an edge portion of the pixel electrode 152. The bank 140 contains a polymer such as a polyimide, a polyester, an acrylic resin, or the like and is provided with a plurality of openings overlapping the pixel electrodes 152 so as to expose the pixel electrodes 152 of the plurality of pixels 104. The formation of the bank 140 securely prevents electrical conduction between adjacent pixel electrodes 152 and fragmentation of the photoluminescence layer 154 and the counter electrode 156 caused by the edge of the pixel electrodes 152.

In the light-emitting element 150, carriers injected from the pixel electrode 152 and the counter electrode 156 recombine in the electroluminescence layer 154, and the resulting energy is generated as light. The carrier injection from the pixel electrode 152 occurs through an interface at which the pixel electrode 152 contacts the electroluminescence layer 154. Therefore, a light-emitting region of each light-emitting element 150 is the region defined by this interface, and the light-emitting element 150 is structured by the pixel electrode 152, the electroluminescence layer 154, and the counter electrode 156 which overlap this interface.

The light-emitting element 150 is configured so that the light obtained in the electroluminescence layer 154 is extracted to the outside through the counter electrode 156. For this purpose, the pixel electrode 152 is configured to have a high reflectance with respect to visible light. In addition, the pixel electrode 152 is preferably configured to inject holes into the electroluminescence layer 154. Thus, for example, the pixel electrode 152 may be configured to have a stacked structure of a film, which has a high reflectance to visible light and contains a metal such as aluminum and silver, and a film, which contains a conductive oxide such as indium-tin oxide (ITO) or indium-zinc oxide (IZO) transmitting visible light and has a relatively high work function, in which the latter is in contact with the electroluminescence layer 154.

The electroluminescence layer 154 is structured by stacking a plurality of functional layers. For example, the electroluminescence layer 154 can be fabricated by stacking a hole injection layer, a hole-transporting layer, an electron-blocking layer, an emission layer, a hole-blocking layer, an electron-transporting layer, an exciton-blocking layer, and an electron injection layer as appropriate. Since these functional layers can be fabricated by appropriately combining known materials, a detailed description is omitted. The hole injection layer, the hole-transporting layer, the electron-transporting layer, the electron injection layer, and the like are configured so that carriers injected from the pixel electrode 152 and the counter electrode 156 are efficiently transported to the emission layer. In addition, the emission layer is formed using, for example, a host and a guest so that recombination efficiently occurs and high emission efficiency can be obtained. Fluorescent or phosphorescent dyes are used as the guests.

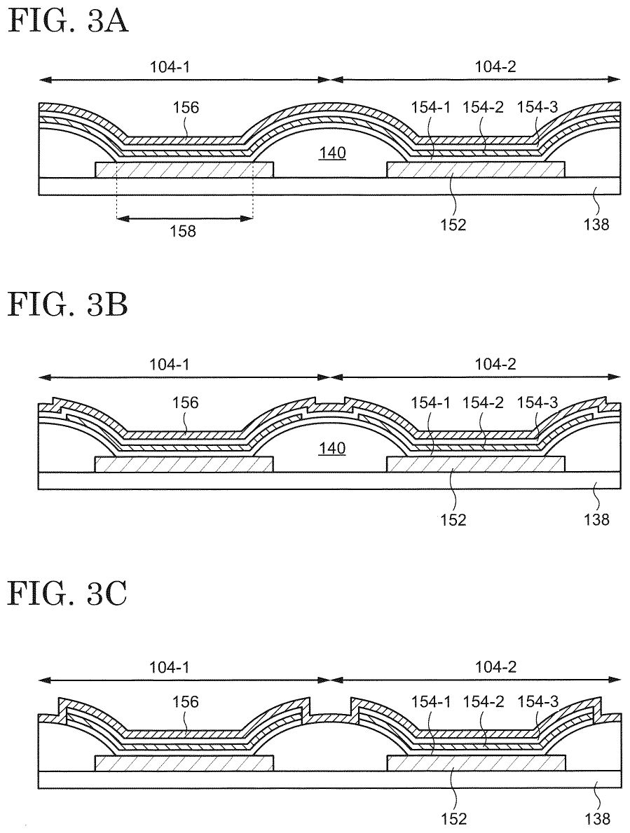

Schematic cross-sectional views of the light-emitting elements 150 arranged in two adjacent pixels 104-1 and 104-2 are shown in FIG. 3A to FIG. 3C. Here, the structures on the substrate 102 side from the second interlayer film 138 are omitted. In addition to the emission layer 154-2 in which the carrier recombination occurs, a hole injection/transporting layer 154-1 and an electron transporting/injection layer 154-3, which are respectively located under and over the emission layer 154-2 and are each composed of one or more functional layers, are illustrated. As shown in FIG. 3A, adjacent pixels 104 may have the light-emitting elements 150 having the same structure, and all functional layers of the light-emitting element 150, including the emission layer 154-2, may be continuous between adjacent pixels 104. Alternatively, the emission layers 154-2 may not be continuous, may be independent, and may have different structures between adjacent pixels 104 (FIG. 3B). This structure allows for different emission colors between adjacent pixels 104. In this case, the functional layers other than the emission layer 154-2, such as the hole injection/transporting layer 154-1 and/or the electron transporting/injection layer 154-3, may have the same structure and be continuous between adjacent pixels 104.

Alternatively, as shown in FIG. 3C, all functional layers including the emission layer 154-2 may be independent without being continuous between adjacent pixels 104. In this case, the structure of the emission layer 154-2 may be identical or different between adjacent pixels 104. As shown in FIG. 3C, when all functional layers are independent without being continuous between adjacent pixels 104, a part of the counter electrode 156 is in contact with the bank 140.

The counter electrode 156 is configured to transmit the light generated in the electroluminescence layer 154. The counter electrode 156 is also preferably configured to efficiently inject electrons into the electroluminescence layer 154. Thus, for example, it is preferable that the counter electrode 156 include a metal (0-valent metal) such as magnesium with a relatively low work function. Moreover, a film containing Mg and Ag obtained by co-evaporation of magnesium and silver or a laminate of this film and a film containing ITO or IZO can also be used. However, since light is extracted through the counter electrode 156, it is preferred to form the counter electrode 156 so that the thickness of the film containing the metal is equal to or more than 5 nm and equal to or less than 15 nm when a film containing a 0-valent metal is used as the counter electrode 156.

### 3. Cap Layer

As an optional component, the display device 100 may have a cap layer 160 provided to cover the light-emitting elements 150 of the plurality of pixels 104 (FIG. 2). The cap layer 160 is provided to be in contact with the counter electrode 156. A micro resonator can be formed over the counter electrode 156 by providing the cap layer 160. Hence, the light passing through the counter electrode 156 is amplified by the interference effect through repeated reflections between the bottom surface of the cap layer 160 (i.e., the interface between the cap layer 160 and the counter electrode 156) and the top surface.

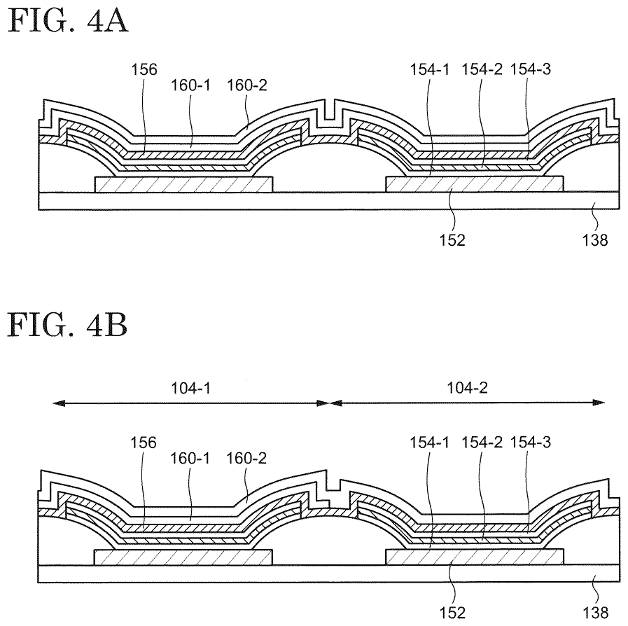

The cap layer 160 may have a single layer structure as shown in FIG. 2 or may have a double layer structure of a first cap layer 160-1 and a second cap layer 160-2 as shown in FIG. 4A. Although not illustrated, the cap layer 160 may have a three-layer structure. Alternatively, the thickness of the cap layer 160 may be different between adjacent pixels 104. In this case, a cap layer 160 with a greater thickness may be provided for the light-emitting element 150 providing light with a longer emission wavelength, thereby forming a resonance structure suitable for the emission wavelength. Thus, for example, when the pixel 104-1 among the adjacent pixels 104-1 and 104-2 provides longer wavelength light emission, the first cap layer 160-1 is selectively disposed over pixel 104-1, and a second cap layer 160-2 may be further disposed over both pixels 104-1 and 104-2 (FIG. 4B).

A material with a high transmittance to visible light is used for the cap layer 160. A polymeric material is typical as such a material, and high refractive index polymeric materials containing sulfur, halogen, or phosphorus are represented. As a polymeric material containing sulfur, a polymer having a substituent such as a thioether, a sulfone, and a thiophene in a main or side chain are represented. As a polymeric material containing phosphorus, a polymeric material containing a phosphite group, a phosphate groups, or the like in a main or side chain and a polyphosphazene are represented. As a polymeric material containing halogen, a polymeric material having bromine, iodine, or chlorine as a substituent is represented. Alternatively, the cap layer 160 may contain an inorganic material. As an inorganic material, titanium oxide, dizirconium oxide, chromium oxide, aluminum oxide, indium oxide, ITO, IZO, lead sulfide, zinc sulfide, and silicon nitride are exemplified. A mixture of these inorganic and polymeric materials may also be used. When a plurality of cap layers 160 is stacked, the materials included in the plurality of cap layers 160 may be identical or different from each other.

The thickness and refractive index of the cap layer 160 are appropriately adjusted so that its optical distance matches or is close to an odd multiple of a quarter of the peak wavelength of the light obtained from the electroluminescence layer 154. This adjustment reduces the half value width of the resulting emission to improve the color purity and increases the luminance in the front direction of the light-emitting element 150.

### 4. Light-Shielding Film and Passivation Film

The display device 100 is further provided with a light-shielding film 162 and a passivation film 170. The light-shielding film 162 is provided to suppress the diffusion of the light from each light-emitting element 150 and to emit highly directional light (collimated light) in the front direction of the display device 100. On the other hand, the passivation film 170 is provided to prevent impurities such as water and oxygen from penetrating into the light-emitting elements 150 and to provide high reliability to the light-emitting elements 150. The structures of the light-shielding film 162 and the passivation film 170 are described below.

As shown in FIG. 2, the passivation film 170 has a structure in which a resin film 174 is sandwiched by two inorganic films (a first inorganic film 172 and a second inorganic film 176). The resin film 174 may be in contact with the first inorganic film 172 and the second inorganic film 176. When the cap layer 160 is provided, the passivation film 170 is provided over the cap layer 160. Therefore, in this case, the first inorganic film 172 may be in contact with the cap layer 160. Each of the first inorganic film 172 and the second inorganic film 176 includes an inorganic oxide containing nitrogen and silicon, such as silicon nitride, silicon nitride oxide, and silicon oxynitride. The first inorganic film 172 and the second inorganic film 176 are each formed by a sputtering method, a CVD method, or the like. The thicknesses of the first inorganic film 172 and the second inorganic film 176 can be selected from a range of equal to or more than 10 nm and equal to or less than 200 nm, for example. On the other hand, the resin film 174 includes a polymer such as a polyimide, a polyester, an acrylic resin, and an epoxy resin and is formed by applying wet deposition methods such as an inkjet method, a printing method, and a spin coating method. The thickness of the resin film 174 may be selected from a range equal to or more than 500 nm and equal to or less than 10 μm, for example.

The light-shielding film 162 has characteristics to reflect or absorb visible light and may include a metal (0-valent metal) such as molybdenum, tungsten, tantalum, copper, and chromium or may be formed with a resin containing black or similarly colored pigments, for example. Alternatively, the light-shielding film 162 may be formed as a carbon film. By using a metal material such as molybdenum, tungsten, tantalum, and copper, which also forms a part of the components of the pixel circuit, it is possible to avoid an increase in process burden and allow the light-shielding film 162 to function as an auxiliary electrode for the counter electrode 156 due to their conductivity. When the light-shielding film 162 contains a 0-valent metal or is a carbon film, the light-shielding film 162 may be formed by a vapor deposition method, a sputtering method, a CVD method, or the like, followed by patterning by photolithography. When the light-shielding film 162 contains a resin, the light-shielding film 162 may be fabricated using an inkjet method or a printing method, or may be fabricated by forming the light-shielding film 162 without an opening as described below with a spin coating method, followed by patterning by photolithography to form the openings.

The thickness of the light-shielding film 162 is appropriately selected so that visible light does not pass through the light-shielding film 162 and the films provided thereover (e.g., the cap layer 160 and the first inorganic film 172) are not cleaved. Specifically, the light-shielding film 162 containing a 0-valent metal may be formed with a thickness in the range equal to or more than 20 nm and equal to or less than 200 nm. When the edge of the light-shielding film 162 is tilted in a range from 20° to 30°, the light-shielding film 162 may have a thickness in the range of equal to or more than 20 nm and equal to or less than 1 μm. When the light-shielding film 162 is a carbon film or contains a resin, the light-shielding film 162 may be formed with a thickness in the range equal to or more than 100 nm and equal to or less than 20 μm.

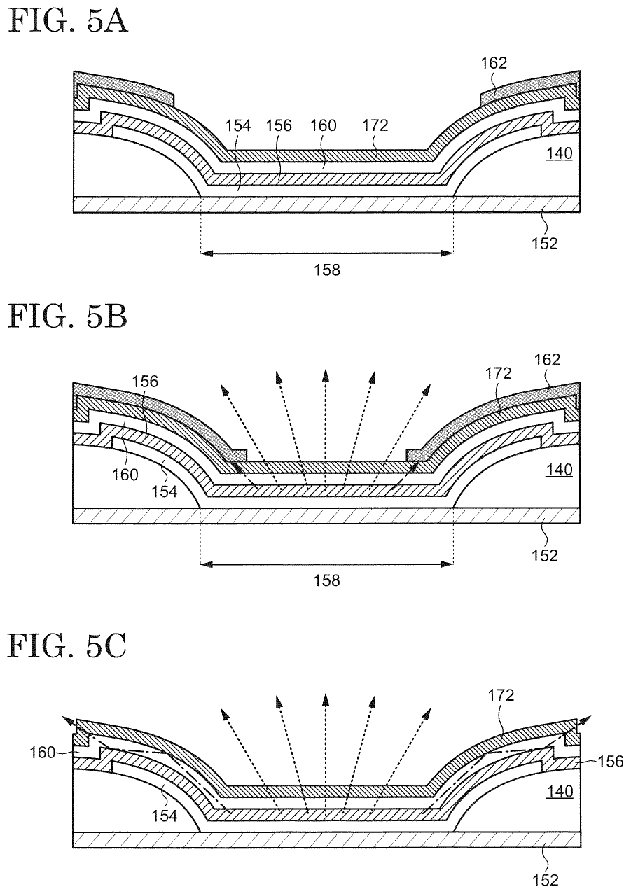

As described above, the light-shielding film 162 is provided to reflect or absorb a part of the light from the light-emitting element 150 so that the light is prevented from radiating outside. For this purpose, the light-shielding film 162 is formed to have a plurality of openings overlapping the pixel electrodes 152 of the light-emitting elements 150 as shown in FIG. 2 so that the pixel electrodes 152 of the light-emitting elements 150 are exposed. At this time, the light-shielding film 162 may be formed so as to overlap the bank 140 but not to overlap the emission region (i.e., the region overlapping the interface between the pixel electrode 152 and the electroluminescence layer 154) 158 of each light-emitting element 150 as shown in FIG. 5A, or may be formed so as to overlap the bank 140 and a part of the light emitting region 158 as shown in FIG. 5B. In the latter case, an area of each opening in the light-shielding film 162 is smaller than that of the light emitting region 158 overlapping the opening.

### 5. Other Component

As an optional component, the display device 100 may have a counter substrate 114 over the passivation film 170 (FIG. 2). The counter substrate 114 includes a material with a high transmittance to visible light so that the light from the light-emitting elements 150 passes through the substrate 114. Thus, the counter substrate 114 is configured to include glass, quartz, ora polymer such as a polyimide, a polyester, and a polycarbonate. Similar to the substrate 102, the counter substrate 114 may have flexibility to the extent that it can be elastically deformed.

When the light-shielding film 162 is not provided, since the light from the electroluminescence layer 154 isotropically travels, the light not only travels in the front direction of the display device 100 (normal direction to the substrate 102) or a direction close thereto (see the dotted arrow in FIG. 5C), but also radiates at various angles as shown in FIG. 5C. As the angle from the front direction increases, a part of the light is repeatedly reflected in the electroluminescence layer 154, the counter electrode 156, the cap layer 160, the bank 140, and the like and spreads to the lateral direction (see the chain arrows in FIG. 5C). The light that spreads in the lateral direction is called stray light. In display devices, for example, ultra-high definition display devices used for head-mounted displays, if stray light is generated, the mixed light of the stray light and the light emitted from the adjacent pixels 104 may be observed, resulting in a decrease in contrast and color purity. In addition, light may be perceived as emission from the light-emitting element 150 which does not actually emit light, which may adversely affect the parallax display required in display devices for embodying virtual reality (VR), augmented reality (AR), and mixed reality (MR).

However, in the display device 100 according to an embodiment of the invention, a part of the light from the light-emitting element 150, more specifically, at least a part of the light emitted at a large angle from the front direction, is reflected or absorbed by the light-shielding film 162 to prevent the light from radiating outside the display device 100. Thus, stray light can be prevented, and light with relatively high directivity can be provided in the front direction. Therefore, even if the display device 100 is applied as a display device for ultra-high definition displays or head-mounted displays, it is possible to provide images with high display quality without causing a decrease in contrast or color purity or adverse effects on parallax display.

Furthermore, in an embodiment of the present invention, the light-shielding film 162 may be provided between the first inorganic film 172 and the resin film 174 so as to be in contact with the first inorganic film 172 and the resin film 174 as shown in FIG. 2, FIG. 5A and FIG. 5B. Thus, the light-shielding film 162 used to reflect or absorb the light can be positioned close to the light-emitting elements 150. On the other hand, since a light-shielding film is provided via a passivation film with a total film thickness ranging from tens to hundreds of micrometers in normal electroluminescence display devices, the distance between the light-emitting elements and the light-shielding film is large. Thus, it is difficult to sufficiently reflect or absorb stray light. In contrast, since the distance between the light-shielding film 162 and the light-emitting elements 150 is small in the display device 100, stray light can be more effectively reflected or absorbed.

### 6. Modified Example

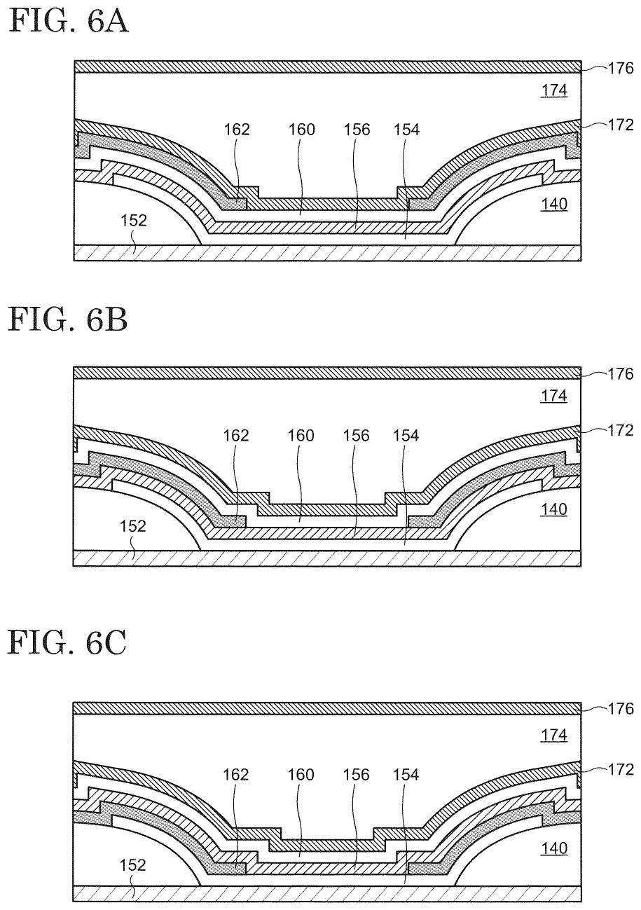

In the aforementioned examples, the light-shielding film 162 is provided between the first inorganic film 172 and the resin film 174 of the passivation film 170 and is separated from the cap layer 160 via the first inorganic film 172 when the cap layer 160 is provided (FIG. 2). However, the position at which the light-shielding film 162 is arranged is not limited thereto. For example, when the cap layer 160 is provided, the light-shielding film 162 may be arranged between the cap layer 160 and the passivation film 170 as shown in FIG. 6A. In this case, the light-shielding film 162 is in contact with the cap layer 160 as well as the first inorganic film 172. Alternatively, the light-shielding film 162 may be disposed between the counter electrode 156 and the cap layer 160 as shown in FIG. 6B. In this case, the light-shielding film 162 is not in contact with the passivation film 170, is separated from the passivation film 170 via the cap layer 160, and is in contact with the counter electrode 156 and the cap layer 160. Furthermore, the light-shielding film 162 may be arranged between the electroluminescence layer 154 and the counter electrode 156 as shown in FIG. 6C. When the arrangement shown in FIG. 6C is employed, the electroluminescence layer 154 may be arranged so as not to be continuous and independent between adjacent light-emitting elements 150, allowing the light-shielding film 162 to be in contact with the bank 140.

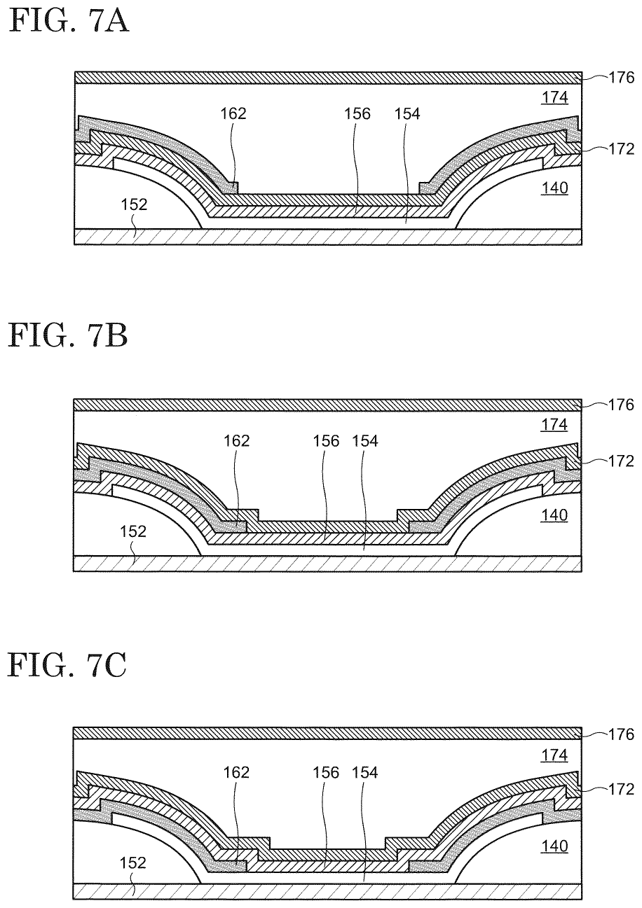

The same is applied when the cap layer 160 is not provided, and the light-shielding film 162 may be disposed between the first inorganic film 172 and the resin film 174 (FIG. 7A) or between the counter electrode 156 and the passivation film 170 (FIG. 7B). In the latter case, the light-shielding film 162 is in contact with the counter electrode 156 and the first inorganic film 172. As shown in FIG. 7C, the light-shielding film 162 may also be arranged between and in contact with the electroluminescence layer 154 and the counter electrode 156.

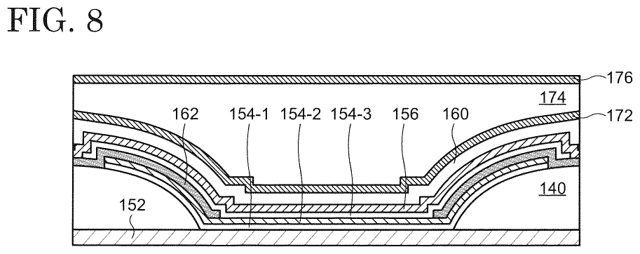

Moreover, the light-shielding film 162 may be disposed in the electroluminescence layer 154. For example, the light-shielding film 162 may be disposed between the emission layer 154-2 and the functional layer (e.g., the electron-transporting layer, the hole-blocking layer, the exciton-blocking layer) provided over the emission layer 154-2 (on the counter electrode 156 side) as shown in FIG. 8. Although not illustrated, the light-shielding film 162 may be arranged between two functional layers arbitrarily selected from the functional layers arranged on the counter electrode 156 side from the emission layer. For example, the light-shielding film 162 may be arranged between the emission layer and the hole-blocking layer, between the emission layer and the electron-transporting layer, between the emission layer and the exciton-blocking layer, as well as between the hole-blocking layer and the electron-transporting layer, between the hole-blocking layer and the exciton-blocking layer, between the electron-transporting layer and the exciton-blocking layer, or between the electron-transporting layer and the electron injection layer.

In these modified examples, since the light-shielding film 162 can be arranged close to the light-emitting elements 150 or the emission layer, stray light can be effectively prevented, thereby producing an ultra-high definition display device with high display quality.

### SECOND EMBODIMENT

In this embodiment, a photosensor device 200 according to an embodiment of the invention is explained. An explanation of the structures the same as or similar to those of the First Embodiment may be omitted.

### 1. Overall Structure

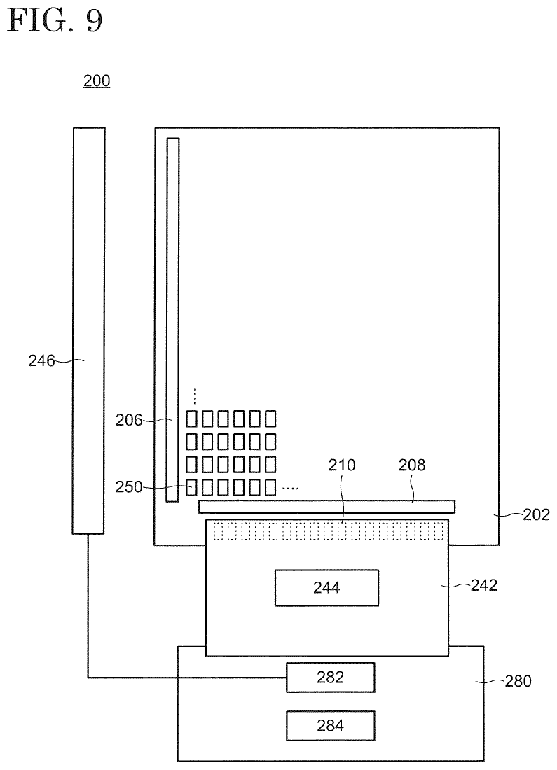

FIG. 9 shows a schematic top view of the photosensor device 200. As shown in FIG. 9, the photosensor device 200 has a substrate 202. The substrate 202 is a base material supporting a plurality of sensor elements (light-receiving elements) 250 described below, sensor circuits connected thereto, and the like and may include glass or quartz, silicon, sapphire, or a polymer such as a polyimide, a polyester, and a polycarbonate, similar to the substrate 102 of the display device 100. The substrate 202 may also have flexibility. A variety of patterned insulating films, conductive films, and semiconductor films are stacked over the substrate 202, thereby forming the plurality of sensor elements 250, driver circuits controlling the sensor elements 250 (scanning line driver circuits 206, signal line driver circuit 208) as well as wirings (not illustrated) connecting the sensor elements 250 and the driver circuits, and the like. The wirings extending from the driver circuits form terminals 210, and the terminals 210 are connected to the control board 280 via a connector 242 such as a flexible printed circuit (FPC) board.

Furthermore, the photosensor device 200 includes a light source 246. The light source 246 has one or a plurality of light-emitting elements such as inorganic light-emitting diodes (LEDs), for example, and is arranged so that an object to be detected by the photosensor device 200 is irradiated with the light. There is no limitation to the wavelength of the light radiated from the light-emitting elements. For example, the light may have a peak wavelength in the visible light region from 400 nm to 800 nm, or in the near infrared region from 800 nm to 2500 nm. The light-emitting elements may also include both a light-emitting element providing a peak wavelength in the visible light region and a light-emitting element providing a peak wavelength in the near-infrared region. When a light-emitting element having a peak wavelength in the visible light region is used, the shape of a finger or a fingerprint can be detected by detecting the light with the sensor elements 250 after the light is reflected on the surface of a human finger, for example. On the other hand, when a light-emitting elements having a peak wavelength in the near-infrared region is used, the light can be detected by the sensor elements 250 after the light is reflected inside the human finger, enabling the detection of internal information of the finger (e.g., biometric information such as blood vessels and pulse rate).

A detection circuit 244 may be provided on the connector 242. The detection circuit 244 is an analog front end (AFE) circuit and is configured to amplify and convert electrical signals supplied from the sensor elements 250 via the signal line driver circuit 208 into a digital signal. A control circuit 282, a power circuit 284, and the like are provided on the control board 280. The control circuit 282 is an FPGA (Field Programmable Gate Array), for example, and supplies control signals to the sensor elements 250, the scanning line driver circuit 206, and the signal line driver circuit 208 to control the detection operation of the sensor elements 250. The control circuit 282 also supplies control signals to the light source 246 and controls the turning on or off of the light source 246. The power circuit 284 is configured to supply voltage signals to the sensor elements 250, the scanning line driver circuit 206, and the signal line driver circuit 208, and to supply power supply voltage for the light-emitting element to the light source 246.

### 2. Structure of Sensor Element

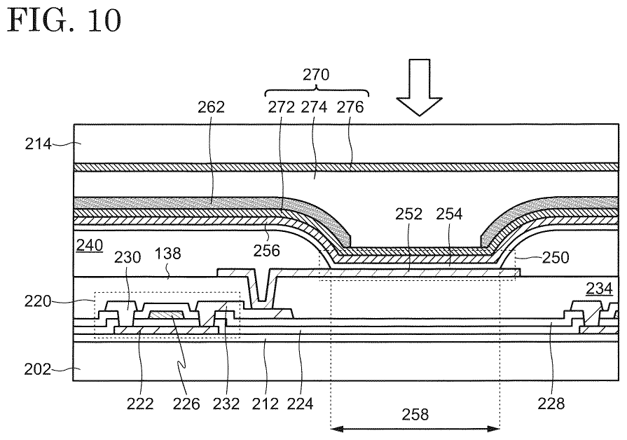

FIG. 10 shows a schematic cross-sectional view of the photosensor device 200 including the sensor elements 250. Similar to each pixel 104 of the display device 100, a sensor circuit for controlling the sensor element 250 is connected to each sensor element 250. Although FIG. 10 shows a single transistor 220 and the sensor element 250 connected thereto, the structure of the sensor circuit may be arbitrarily selected, and the sensor circuit may be appropriately structured with one or more transistors and capacitor elements.

As shown in FIG. 10, the sensor circuit including the transistor 220 and the like is provided over the substrate 202 directly or through an undercoat 212 which is an optional component. Similar to the undercoat 112, the undercoat 212 may be composed of one or more films containing a silicon-containing inorganic compound. The transistor 220 illustrated in FIG. 10 includes a semiconductor film 222, a gate insulating film 224 over the semiconductor film 222, a gate electrode 226 over the gate insulating film 224, and a first interlayer film 228 over the gate electrode 226 as well as a source electrode 230 and the drain electrode 232 electrically connected to the semiconductor film 222 through openings formed in the gate insulating film 224 and the first interlayer film 228. The structure of the transistor 220 shown here is an example, and similar to the display device 100, transistors having various configurations can be arranged in each pixel circuit. Since the structure of the transistor 220 is similar to that of the transistor 120 of the display device 100, a detailed description is omitted.

A planarization film 234 is provided over the transistor 220, and the sensor element 250 is disposed over the planarization film 234. The sensor element 250 includes, as fundamental components, a first electrode 252, a photoelectric conversion layer 254 over the first electrode 252, and a second electrode 256 over the photoelectric conversion layer 254. The first electrode 252 is electrically connected to the drain electrode 232 exposed in an opening in the planarization film 234 either directly or via a connecting electrode or the like which is not illustrated.

A bank 240 is provided over the first electrode 252 to cover an edge portion of the first electrode 252. The bank 240 also includes a polymer such as a polyimide, a polyester, an acrylic resin, or the like and has a plurality of openings overlapping the first electrodes 252 so as to expose the plurality of first electrodes 252. The formation of the bank 240 securely prevents electrical conduction between adjacent first electrodes 252 and fragmentation of the photoelectric conversion layer 254 and the second electrode 256 caused by the edge portion of the first electrodes 252.

In the sensor element 250, a pulse voltage is applied to one of the first electrode 252 and the second electrode 256 (e.g., the second electrode 256). When light is incident on the photoelectric conversion layer 254 (see the hollow arrow in FIG. 10.), the voltage-current characteristic, the resistance value, or the like of the photoelectric conversion layer 254 changes, which causes a fluctuation of the potential of the other electrode (e.g., the first electrode 252). This fluctuation is supplied to the detection circuit 244 via the signal line driver circuit 208 and amplified. Since this potential fluctuation corresponds to the amount of the light applied to and detected by the sensor element 250, information about the object can be obtained by using the amount of the light detected by the plurality of sensor elements 250.

Therefore, the sensor elements 250 are configured so that light is incident on the photoelectric conversion layer 254 via the second electrode 256. Accordingly, the second electrode 256 is configured to have a high transmittance to visible light and/or near infrared light. For example, the second electrode 256 is configured to include a conductive oxide such as ITO or IZO exhibiting transmittance with respect to visible light. Alternatively, the second electrode 256 may be configured to include a film containing a metal such as aluminum, silver, magnesium, or the like with a thickness (e.g., equal to or more than 5 nm and equal to or less than 15 nm) allowing visible light and/or near infrared light to pass therethrough. On the other hand, the first electrode 252 may be configured to include a conductive oxide such as ITO or IZO.

The structure of the photoelectric conversion layer 254 is also arbitrarily determined, and a stack of a plurality of functional layers such as a hole-transporting layer, an electron-transporting layer, an active layer, and the like may be used as the photoelectric conversion layer 254. Since known organic compounds such as a fullerene and its derivatives, a metal phthalocyanine such as copper phthalocyanine and its derivatives, a condensed aromatic compound such as rubrene and perylene and its derivatives, and the like can be used for these functional layers, a detailed explanation is omitted. Although not illustrated, similar to the electroluminescence layer 154 of the display device 100, adjacent sensor elements 250 may have the same structure, and all functional layers may be continuous between adjacent sensor elements 250. Alternatively, all functional layers may be independent without continuity between adjacent sensor elements 250. In this case, a part of the second electrode 256 is in contact with the bank 240.

### 3. Light-Shielding Film and Passivation Film

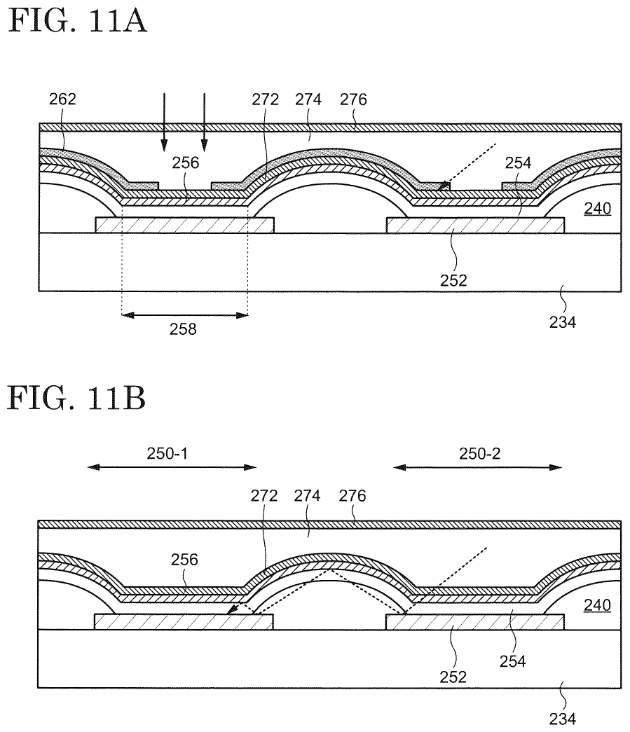

Similar to the display device 100, the photosensor device 200 according to an embodiment of the invention is further provided with a light-shielding film 262 and a passivation film 270. The light-shielding film 262 is provided so that light traveling to each sensor element 250 in a front direction or a direction close thereto is selectively incident on the sensor elements 250. More specifically, the light-shielding film 262 is provided so that light is incident on the sensor elements 250 at an incidence angle equal to or more than 0° and equal to or less than 60°, equal to or more than 0° and equal to or less than 45°, or equal to or more than 0° and equal to or less than 30° relative to the sensor element 250 (or the second electrode 256) as shown by the solid arrows in FIG. 11A and that the light incident at a large angle (e.g., more than 60° and less than 90°, more than 45° and less than 90°, or more than 30° and less than 90°) is reflected or absorbed as shown by the dotted arrow in FIG. 11A. On the other hand, the passivation film 270 is provided to prevent impurities such as water and oxygen from penetrating into the sensor elements 250 and to provide high reliability to the sensor elements 250. The structures of the light-shielding film 262 and the passivation film 270 are described below.

The passivation film 270 has a structure in which a resin film 274 is sandwiched by two inorganic films (first inorganic film 272 and second inorganic film 276) as shown in FIG. 10 and FIG. 11A. Since this structure is similar to the passivation film 170 of the display device 100, a detailed explanation is omitted.

The structure of the light-shielding film 262 is also similar to that of the light-shielding film 162 of the display device 100. That is, in order to reflect or absorb the light incident at a large incident angle and prevent the light from entering the photoelectric conversion layer 254, the light-shielding film 262 is formed so as to have a plurality of openings overlapping the first electrodes 252 to expose the first electrodes 252 of the sensor elements 250 as shown in FIG. 10 and FIG. 11A. At this time, that light-shielding film 262 may be formed so that the light-shielding film 262 overlaps the bank 240 but does not overlap a region 258 where the first electrode 252 of each sensor element 250 is exposed from the bank 240 (see FIG. 10) or may be formed so that the light-shielding film 262 overlaps the bank 240 and a part of the region 258 as shown in FIG. 10 and FIG. 11A. In the latter case, an area of each opening in the light-shielding film 262 is smaller than an area of the region 258 overlapping the opening.

In the case where the light-shielding film 262 is not provided, the light reflected by the object enters the sensor element 250 at various incident angles. Therefore, when the light incident at a large angle enters the bank 240 or the sensor element 250 which is not intended to receive light (e.g., the sensor element 250-2 shown in FIG. 11B), a part of the light also repeatedly reflects in the photoelectric conversion layer 254, the second electrode 256, the bank 240, and the like, spreads in the lateral direction, and then enters the intended sensor element (sensor element 250-1 shown in FIG. 11B). When this phenomenon occurs, the signal/noise ratio and the identification accuracy of the sensor position may decrease.

However, in the photosensor device 200 according to an embodiment of the present invention, the light with an incident angle equal to or larger than a certain value is reflected or absorbed by the light-shielding film 262 so that the light with a small incident angle can be selectively received and its intensity can be determined. Thus, the unintended light is prevented from entering the sensor element 250 and the identification accuracy of the sensor position is improved. In addition, since a high signal/noise ratio can be ensured, high detection accuracy can be obtained.

Moreover, in an embodiment of the invention, the light-shielding film 262 may be provided between the first inorganic film 272 and the resin film 274 so as to be in contact with these components as shown in FIG. 10 and FIG. 11A. Therefore, the light-shielding film 262 used to reflect or absorb light can be arranged close to the sensor elements 250. As a result, unlike the case where the light-shielding film 262 is provided over the passivation film 270, the light with a large incident angle can be more effectively reflected or absorbed.

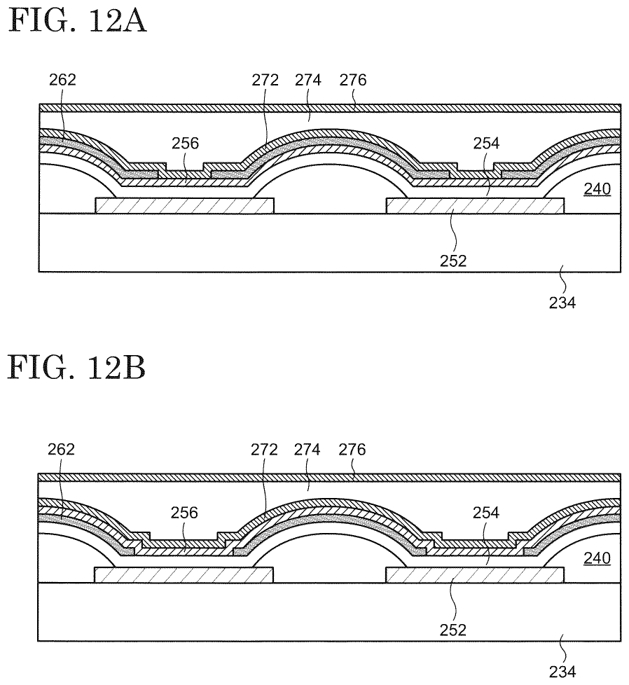

Note that the position of the light-shielding film 262 is not limited to that described above. For example, the light-shielding film 262 may be disposed between the sensor elements 250 and the passivation film 270 (i.e., between the second electrode 256 and the first inorganic film 272) as shown in FIG. 12A. In this case, the light-shielding film 262 is in contact with the second electrode 256 and the first inorganic film 272 and is spaced away from the resin film 274. Alternatively, the light-shielding film 262 may be provided within the sensor element 250. Specifically, the light-shielding film 262 may be provided between the photoelectric conversion layer 254 and the second electrode 256 as shown in FIG. 12B. Alternatively, although not illustrated, the light-shielding film 262 may be provided between the active layer and the functional layer (e.g., the hole-transporting layer) on the side of the second electrode 256 than the active layer.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A display device comprising:
a plurality of pixels each comprising a light-emitting element including a pixel electrode, an electroluminescence layer over the pixel electrode, and a counter electrode over the electroluminescence layer;
a first inorganic film over the counter electrode;
a light-shielding film located over the first inorganic film and having a plurality of openings overlapping the pixel electrodes of the plurality of pixels;
a resin film located over the light-shielding film and the first inorganic film and in contact with the first inorganic film; and
a second inorganic film over the resin film.

2. The display device according to claim 1,
wherein the light-shielding film is in contact with the first inorganic film.

3. The display device according to claim 1,
wherein the resin film is in contact with the light-shielding film and the first inorganic film.

4. The display device according to claim 1, further comprising a cap layer between the counter electrode and the first inorganic film.

5. The display device according to claim 4,
wherein the cap layer is in contact with the counter electrode.

6. The display device according to claim 4,
wherein the first inorganic film is in contact with the cap layer.

7. The display device according to claim 1, further comprising a bank located over the pixel electrodes, having a plurality of openings exposing the pixel electrodes of the plurality of pixels, and covered by the electroluminescence layer,
wherein, in each of the plurality of pixels, a region in which the pixel electrode and the electroluminescence layer are in contact with each other is partly covered by the light-shielding film.

8. A display device comprising:
a plurality of pixels each comprising a light-emitting element including a pixel electrode, an electroluminescence layer over the pixel electrode, and a counter electrode over the electroluminescence layer;
a light-shielding film located over the counter electrode and having a plurality of openings overlapping the pixel electrodes of the plurality of pixels;
a first inorganic film over the light-shielding film and the counter electrode;
a resin film located over and in contact with the first inorganic film; and
a second inorganic film over and in contact with the resin film.

9. The display device according to claim 8,
wherein the light-shielding film is in contact with the counter electrode.

10. The display device according to claim 8,
wherein the first inorganic film is in contact with the light-shielding film and the counter electrode.

11. The display device according to claim 8, further comprising a cap layer between the light-shielding film and the counter electrode.

12. The display device according to claim 8, further comprising a cap layer between the light-shielding film and the first inorganic film.

13. The display device according to claim 8, further comprising a bank located over the pixel electrodes, having a plurality of openings exposing the pixel electrodes of the plurality of pixels, and covered by the electroluminescence layer,
wherein, in each of the plurality of pixels, a region in which the pixel electrode and the electroluminescence layer are in contact with each other is partly covered by the light-shielding film.

14. A display device comprising:
a plurality of pixels each comprising a light-emitting element including a pixel electrode, an electroluminescence layer over the pixel electrode, and a counter electrode over the electroluminescence layer;
a light-shielding film located between the electroluminescence layer and the counter electrode and having a plurality of openings overlapping the pixel electrodes of the plurality of pixels;
a first inorganic film over the light-shielding film and the counter electrode;
a resin film over and in contact with the first inorganic film; and
a second inorganic film over the resin film.

15. The display device according to claim 14,
wherein the light-shielding film is in contact with the electroluminescence layer.

16. The display device according to claim 14,
wherein the first inorganic film is in contact with the counter electrode.

17. The display device according to claim 14, further comprising a cap layer between the counter electrode and the first inorganic film.

18. The display device according to claim 17,
wherein the cap layer is in contact with the counter electrode.

19. The display device according to claim 17,
wherein the first inorganic film is in contact with the cap layer.

20. The display device according to claim 14, further comprising a bank located over the pixel electrodes, having a plurality of openings exposing the pixel electrodes of the plurality of pixels, and covered by the electroluminescence layer,
wherein, in each of the plurality of pixels, a region in which the pixel electrode and the electroluminescence layer are in contact with each other is partly covered by the light-shielding film.
